(19) United States
(12) Patent Application Publication
(10) Pub. No.: US 2004/0104389 A1
(43) Pub. Date: Jun. 3, 2004

(54) [A POLYSILICON THIN FILM TRANSISTOR]

(76) Inventor: KUN-HONG CHEN, TAIPEI (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/605,159

(22) Filed: Sep. 12, 2003

(30) Foreign Application Priority Data
Oct. 16, 2002 (TW) 91123797

(51) Int. Cl. H01L 29/04

(52) U.S. Cl. 257/72

(57) ABSTRACT

A polysilicon thin film transistor having a poly-island layer, a gate, a gate insulating film, a first inter-layer dielectric and a second inter-layer dielectric. The poly-island layer includes a channel region and a doped source/drain region on each side of the channel. The gate insulating film includes a silicon oxide layer and a silicon nitride layer. The gate is positioned over the poly-island layer. The oxide layer is positioned between the gate and the poly-island layer and the nitride layer is positioned between the gate and the oxide layer. The first inter-layer dielectric covers the gate and the nitride layer and the second inter-layer dielectric covers the first inter-layer dielectric. A source/drain contact metal is embedded between the first inter-layer dielectric and the gate insulating film on each side of the gate. The source/drain contact metal is electrically connected to one of the doped source/drain region.

### CROSS REFERENCE TO RELATED APPLICATIONS

This application claims the priority benefit of Taiwan application serial no. 91123797, filed on Oct. 16, 2002.

### BACKGROUND OF INVENTION

1. Field of Invention

The present invention relates to a thin film transistor (TFT). More particularly, the present invention relates to a timing control method of a polysilicon thin film transistor.

2. Description of Related Art

Due to rapid progress in electronic technologies, digitized video or imaging devices have become an indispensable product in our daily life. Among video and imaging products, displays are the principle devices used for providing information. Through a display device, a user is able to obtain information or to control various operations. To facilitate the users, most video or imaging equipment is now designed with a slim and fairly light body. With breakthroughs in opto-electronic technologies and advances in semiconductor fabrication techniques, flat panel type displays such as a thin film transistor liquid crystal display (TFT-LCD) are out in the market.

Recently, a technique for forming a thin film transistor liquid crystal display fabricated having polysilicon thin film transistors has been developed. The thin film transistor in this type of display has electron mobility much greater than a conventional amorphous silicon (a-Si) type of thin film transistor. Since a display with a smaller thin film transistor and a larger aperture ratio can be produced, a brighter display with lower power consumption is obtained. Moreover, due to the increase in electron mobility, a portion of the driving circuit and the thin film transistor may be fabricated on a glass substrate together at the same time. Thus, reliability and quality of the liquid crystal display panel is improved and the production cost relative to a conventional amorphous silicon type of thin film transistor liquid crystal display is much lower. Furthermore, because polysilicon is a lightweight material with the capacity to produce high-resolution display without consuming too much power, a polysilicon thin film transistor display is particularly appropriate for installing on a portable product whose body weight and energy consumption is critical.

Earlier generations of polysilicon thin film transistor were fabricated using solid phase crystallization (SPC) method at temperature higher than 1000° C. With such a high processing temperature, a quartz substrate must be used. Since quartz substrate costs more than a glass substrate and is also subjected to dimensional limitation (not more than 2 to 3 inches in size), polysilicon thin film transistor was only used in small panel display. Later, with the development of laser and maturation of laser crystallization or excimer laser annealing (ELA) techniques, an amorphous silicon film can be easily re-crystallized into polysilicon through a laser scanning operation at a temperature below 600° C. Hence, a glass substrate suitable for forming conventional amorphous silicon TFT-LCD can also be used to fabricate a polysilicon TFT-LCD having larger panel size. Because a lower fabrication temperature is required, this type of polysilicon is often referred to as a low temperature polysilicon (LTPS).

FIG. 1 is a schematic cross-sectional view of a conventional polysilicon thin film transistor (TFT). As shown in FIG. 1, a conventional polysilicon thin film transistor 10 typically includes a poly-island layer 102, an oxide gate insulation film 104, a gate 106 and a first and a second inter-layer dielectric (ILD) 108, 109 over a substrate 100. The poly-island layer 102 includes a channel region 102a under the gate 106, a doped source/drain region 102b on each side of the channel region 102a and a lightly doped drain (LDD) region 102c between the channel region 102a and the doped source/drain region 102b. The gate 106 is positioned over the channel region 102a and the oxide gate insulating film 104 is positioned between the gate 106 and the poly-island layer 102. The first inter-layer dielectric 108 covers the gate 106 and the gate insulating film 104. Furthermore, a source/drain contact metal 110 is embedded between the first inter-layer dielectric 108 and the gate insulating film 104 on each side of the gate 106. The source/drain contact metal 110 is electrically connected to the doped source/drain region 102b. The second inter-layer dielectric 109 is positioned over the thin film transistor device.

However, due to poor production quality of the oxide gate insulating film, most polysilicon thin film transistors have a stress related reliability problem that often occurs in the transistor device. FIGS. 2A and 2B are graphs showing the relationship between drain current (I_{D}) and gate voltage (V_{G}) Of two conventional polysilicon thin film transistors each having a different poly-island aspect ratio obtained after repeated operations. The graphs are obtained when a drain voltage (V_{D}) of about 10V is applied to polysilicon thin film transistors with a poly-island layer having a width/length ratio of 30/6 and 60/6 respectively and an oxide gate insulating film having a thickness of about 1000 Å. As shown in FIGS. 2A and 2B, a normal I-V curve is obtained when the polysilicon thin film transistor is operated for the first time. However, for the second and operations thereafter, the I-V curve shifts progressively and rarely overlaps. Since the I-V operating curve of a conventional polysilicon thin film transistor is highly non-repetitive, reliability of a conventional polysilicon thin film transistor device is usually poor.

### SUMMARY OF INVENTION

Accordingly, one object of the present invention is to provide a polysilicon thin film transistor having an improved reliability of operation and performance.

A second object of this invention is to provide a polysilicon thin film transistor capable of tracing out an overlapping current/voltage (I-V) curve during repeated operation.

To achieve these and other advantages and in accordance with the purpose of the invention, as embodied and broadly described herein, the invention provides a polysilicon thin film transistor over a substrate. The polysilicon thin film transistor includes a poly-island layer having a channel region and a doped source/drain region on each side of the channel region, a gate, a gate insulating film comprising an oxide layer and a nitride layer and an inter-layer dielectric (ILD). The gate is positioned over the poly-island layer. The oxide layer is formed between the gate and the poly-island layer and the nitride layer is formed between the gate and the oxide layer. The inter-layer dielectric includes a first inter-layer dielectric and a second inter-layer dielectric. The first inter-layer dielectric covers the gate and the nitride layer while the second inter-layer dielectric covers the first inter-layer dielectric. A source/drain contact is embedded between the first inter-layer dielectric and the gate insulating film on each side of the gate. The source/drain contact is electrically connected to the doped source/drain region of the poly-island layer.

The polysilicon thin film transistor according to this invention employs a gate insulating film that includes an oxide layer and a nitride layer. The composite gate insulating film reinforces the repeatability of electrical characteristics in repeated operations and hence improves transistor reliability.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional polysilicon thin film transistor.

FIGS. 2A and 2B are graphs showing the relationship between drain current (I_{D}) and gate voltage (V_{G}) of two conventional polysilicon thin film transistors each having a different poly-island aspect ratio obtained after repeated operations.

FIG. 3 is a schematic cross-sectional view of a polysilicon thin film transistor according to one preferred embodiment of this invention.

FIGS. 4A and 4B are graphs showing the relationship between drain current (I_{D}) and gate voltage (V_{G}) of two polysilicon thin film transistors each having a different poly-island aspect ratio obtained after repeated operations, wherein the polysilicon thin film transistors are fabricated according to this invention with the gate insulating film comprising a nitride layer having a thickness of about 200 Å and an oxide layer having a thickness of about 1000 Å.

FIGS. 5A and 5B are graphs showing the relationship between drain current (I_{D}) and gate voltage (V_{G}) of two polysilicon thin film transistors each having a different poly-island aspect ratio obtained after repeated operations, wherein the polysilicon thin film transistors are fabricated according to this invention with the gate insulating film comprising a nitride layer having a thickness of about 400 Å and an oxide layer having a thickness of about 1000 Å.

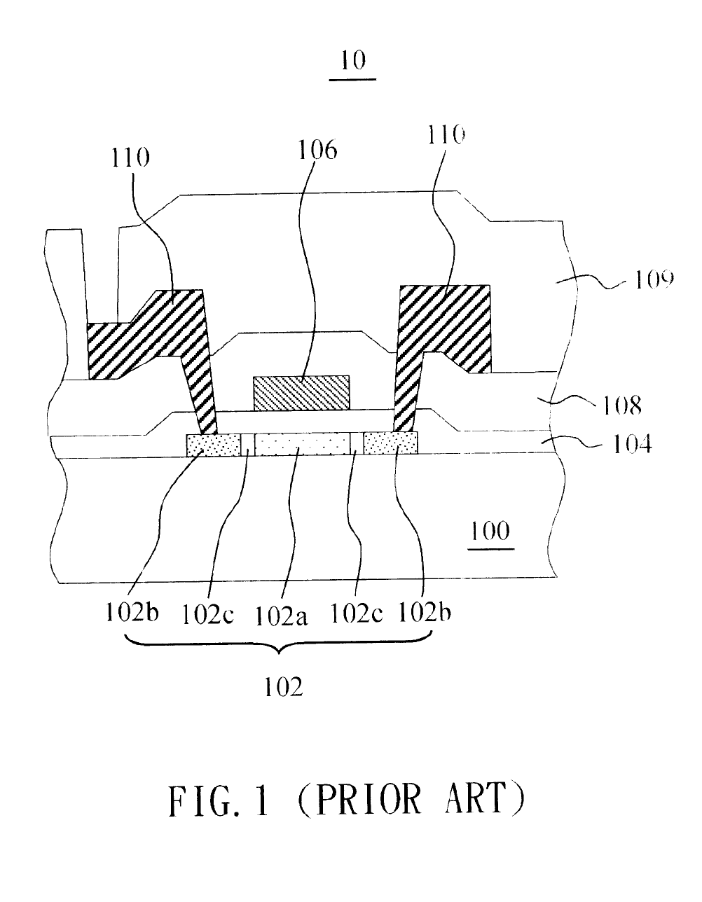

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

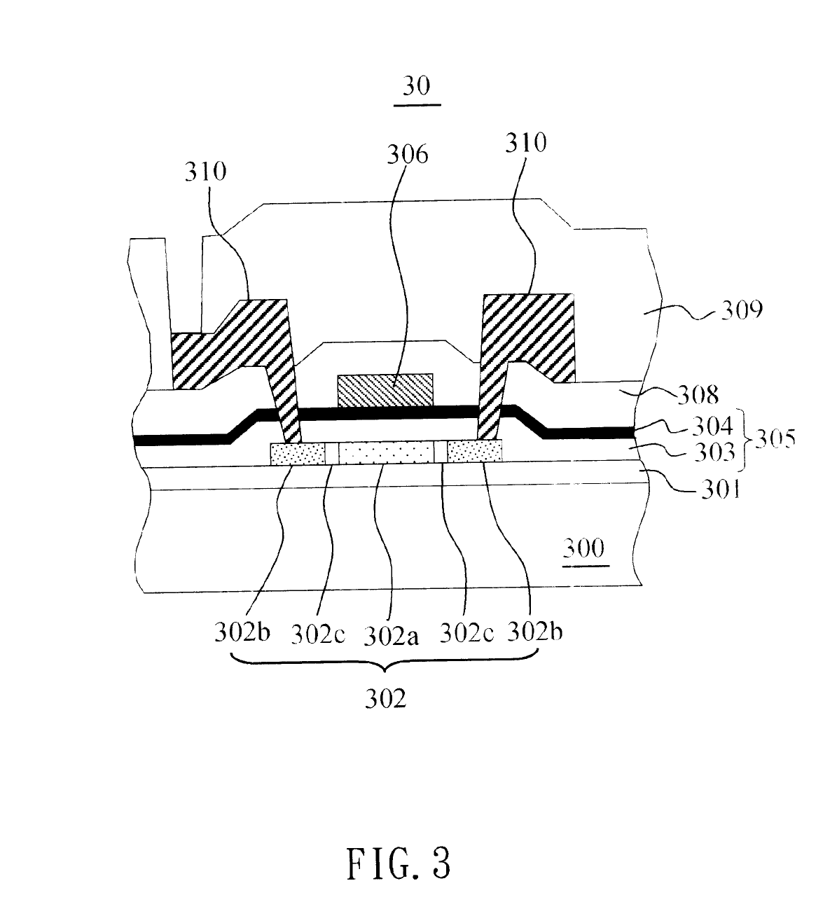

FIG. 3 is a schematic cross-sectional view of a polysilicon thin film transistor according to one preferred embodiment of this invention. The polysilicon thin film transistor (TFT) 30 includes a poly-island layer 302, a composite gate insulating film 305 comprising of a silicon oxide layer 303 and a silicon nitride layer 304, a gate 306 and a first and second inter-layer dielectric 308, 309 over a substrate 300. The poly-island layer 302 includes a channel region 302a under the gate 306 and a doped source/drain region 302b such as a P-doped region or an N-doped region on each side of the channel region 302a. A lightly doped drain (LDD) 302c may also be formed between the channel region 302a and the doped source/drain region 302b. In addition, the nitride layer 304 in the gate insulating film 305 has a thickness between about 50 Å to 400 Å and the oxide layer 303 has a thickness between 100 Å to 1400 Å.

As shown in FIG. 3, the gate 306 is formed over the channel region 302a. The oxide layer 303 of the gate insulating film 305 is formed between the gate 306 and the poly-island layer 302. The oxide layer 303 preferably has a thickness smaller than 1400 Å. The nitride layer 304 of the gate insulating film 305 is formed between the gate 306 and the oxide layer 303. The nitride layer 304 preferably has a thickness smaller than 400 Å. The first inter-layer dielectric 308 covers the gate 306 and the gate insulating film 305. A source/drain contact metal 310 is also embedded between the first inter-layer dielectric 308 and the gate insulating film 305 on each side of the gate 306. The source/drain contact metal 310 is electrically connected to the doped source/drain region 302b. The second inter-layer dielectric 309 is formed over the transistor. Furthermore, to prevent the diffusion of impurities from the glass substrate 300 of a thin film transistor liquid crystal display, a buffer layer 301 is often formed directly over the substrate 300.

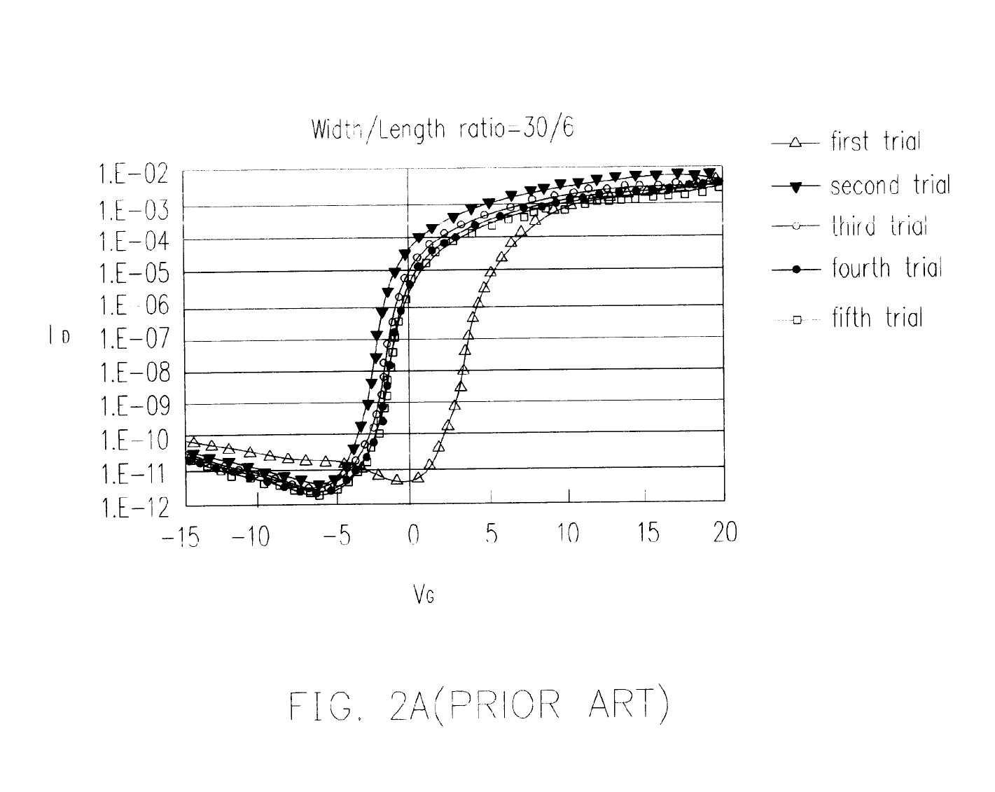

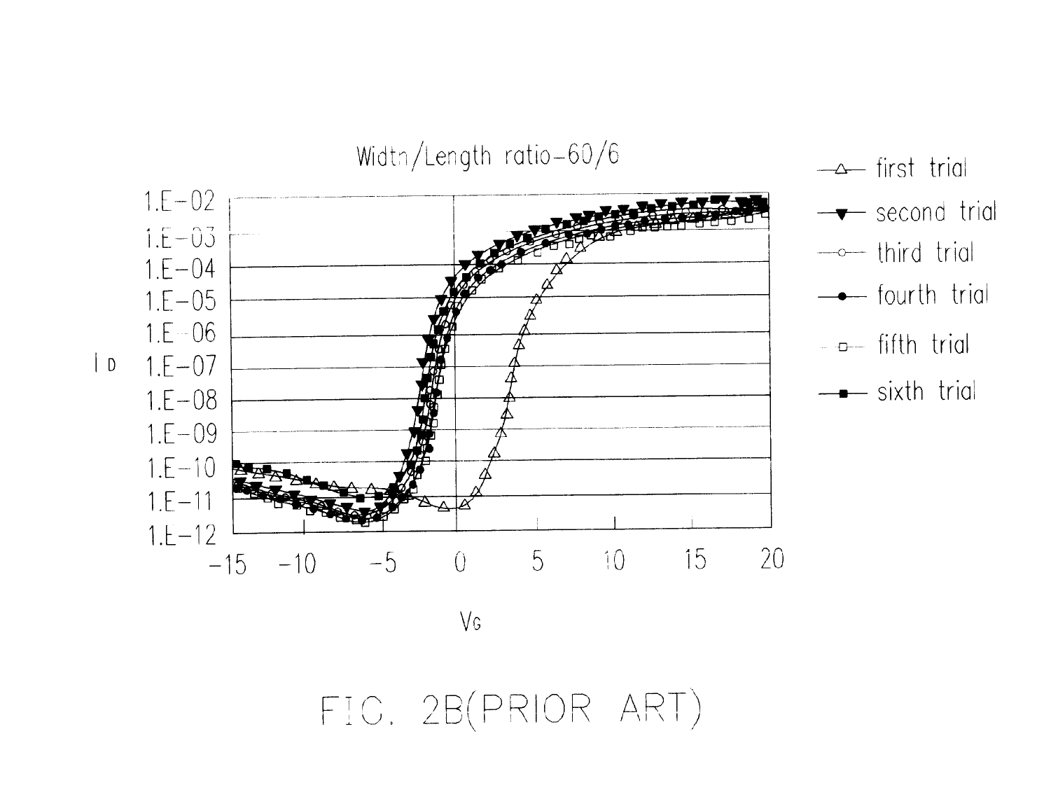

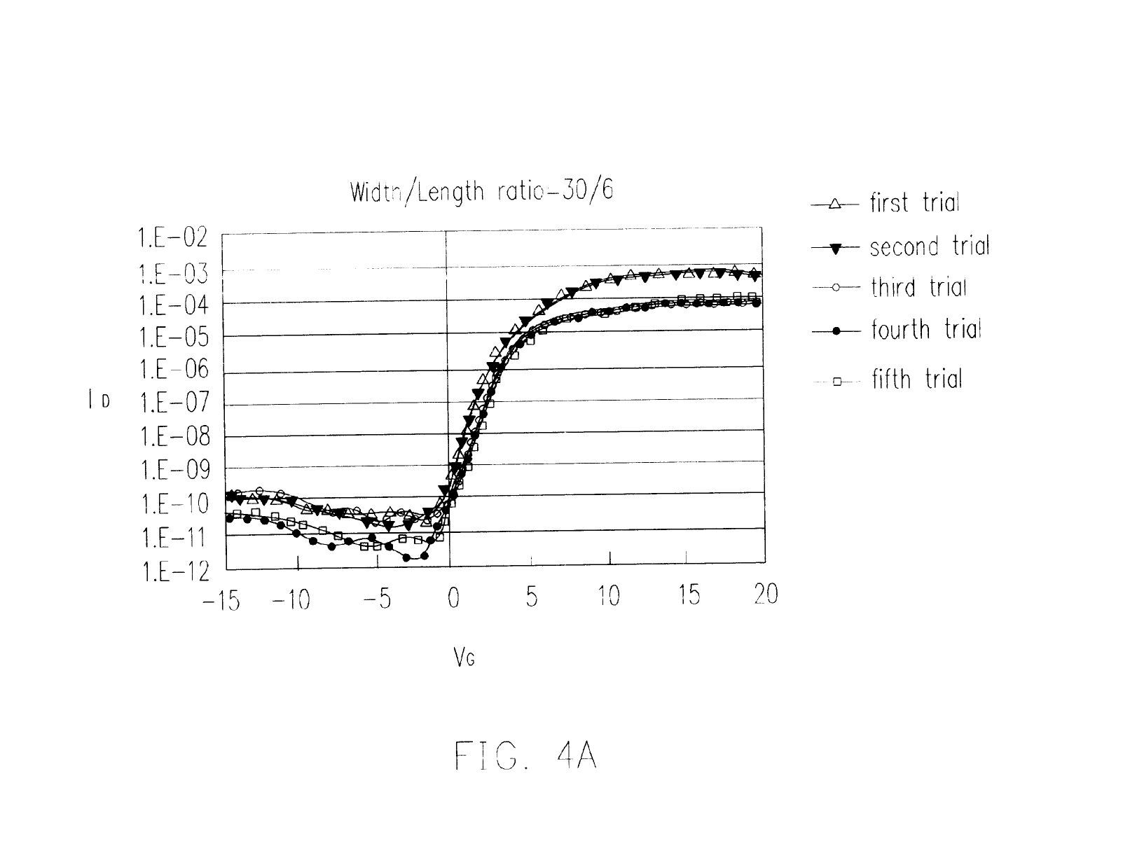

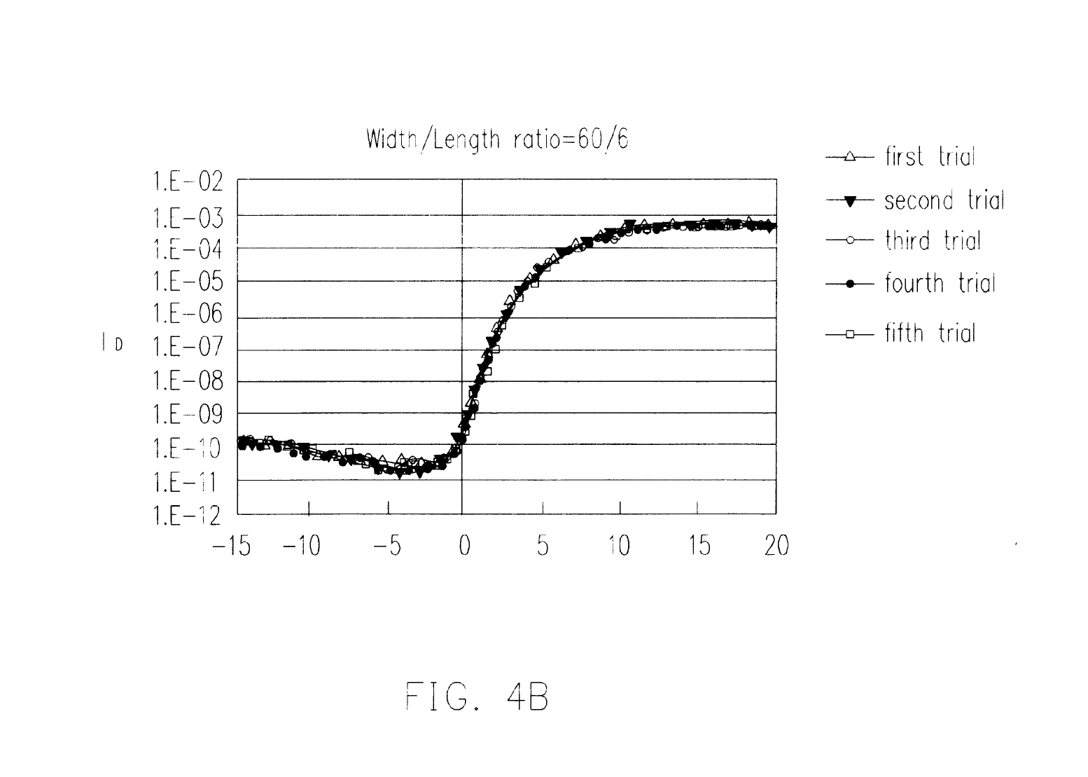

To indicate the improvement in reliability of the polysilicon thin film transistor of this invention relative to a conventional design, refer to FIGS. 4A and 4B. FIGS. 4A and 4B are graphs showing the relationship between drain current (I_{D}) and gate voltage (V_{G}) of two polysilicon thin film transistors each having a different poly-island aspect ratio obtained after repeated operations. The polysilicon thin film transistors are fabricated according to this invention with the gate insulating film comprising a nitride layer having a thickness of about 200 Å and an oxide layer having a thickness of about 1000 Å. During operation, a voltage of about 10V is applied to the drain terminal (V_{D}). As shown in FIGS. 4A and 4B, the I-V curve is able to maintain at a fixed position for a poly-island layer at a width/length ratio of 30/6 or 60/6 under repeated operations. Thus, compared with the I-V curve in FIGS. 2A and 2B with large shifting after repeated operations, reliability of the polysilicon thin film transistor fabricated according to this invention is improved considerably.

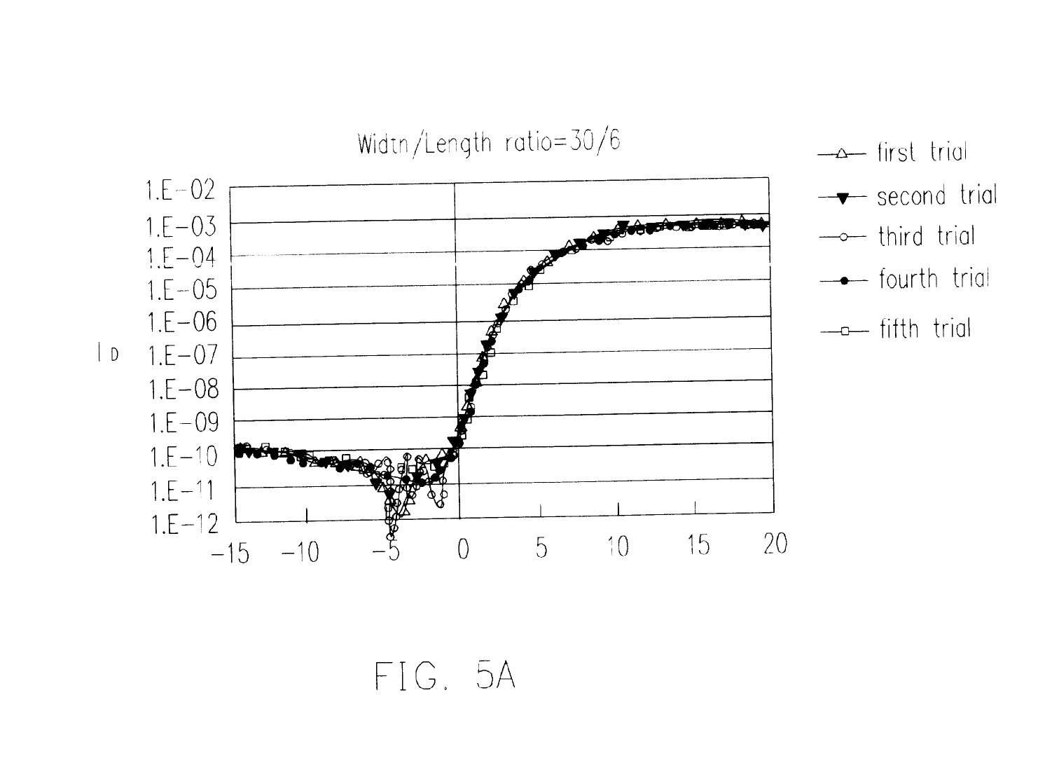

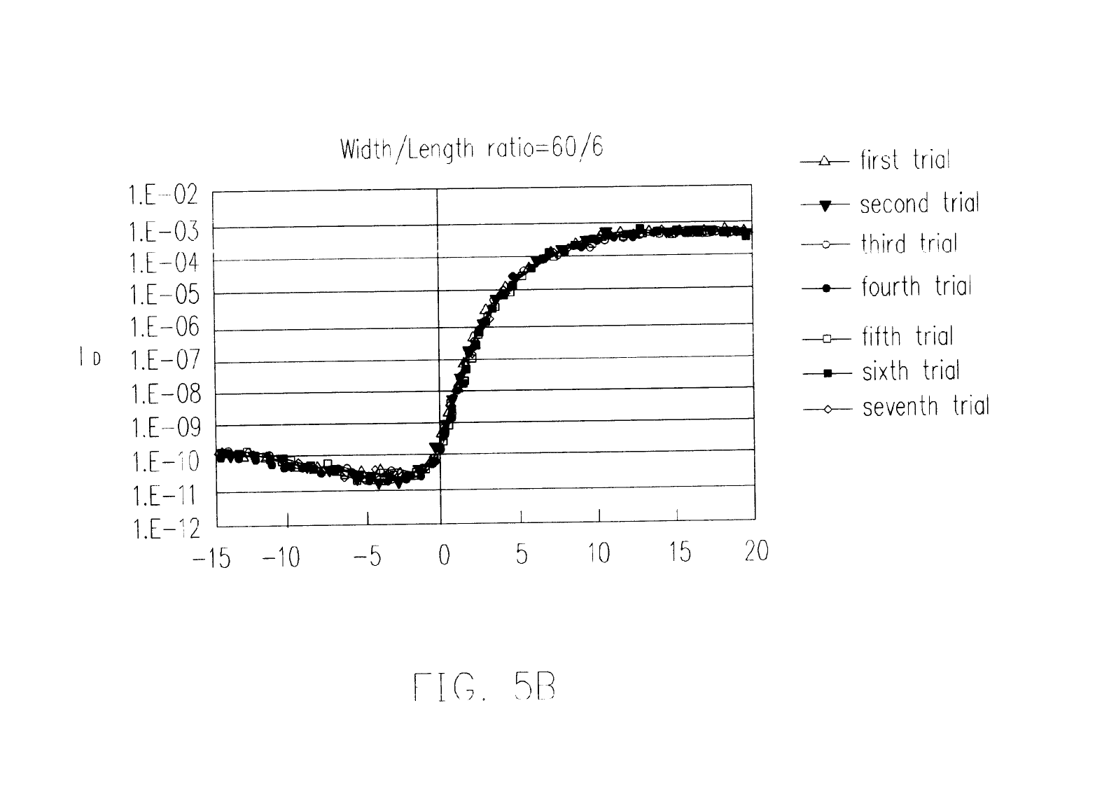

When the nitride layer in the polysilicon thin film transistor fabricated according to this invention is increased to 400 Å, the I-V curve after repeated operation of the transistor is shown in FIGS. 5A and 5B. As shown in FIGS. 5A and 5B, the I-V curve is more stable as the nitride layer is increased from 200 Å (in FIGS. 4A and 4B) to 400 Å. With a thicker nitride layer, the capacity of the polysilicon thin film transistor to withstand stress is increased and hence overall reliability of the transistor is further improved. Since the I-V curve of the polysilicon thin film simply overlaps on repeated operations as thickness of the nitride layer is increased to 400 Å and increasing the thickness of the nitride layer has minor effect on device miniaturization, the nitride layer is preferably set to around 400 Å.

In conclusion, one major aspect of the polysilicon thin film transistor according to this invention is that a composite gate insulating film comprising of an oxide layer and a nitride layer is deployed. The composite gate insulating film reinforces the repeatability of electrical characteristics in repeated operations so that performance and reliability of the transistor is improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A polysilicon thin film transistor, comprising:
a substrate;
a poly-island layer over the substrate, wherein the poly-island layer having:
a channel region, and
a doped source/drain region on each side of the channel region;
a gate over the channel region of the poly-island layer;
a gate insulating film between the gate and the poly-island layer, the gate insulating film further comprising:
a silicon oxide layer covering the poly-island layer; and
a silicon nitride layer between the silicon oxide layer and the gate; and
an inter-layer dielectric over the gate and the gate insulating film.

2. The polysilicon thin film transistor of claim 1, wherein the silicon oxide has a thickness between about 100 Å to 1400 Å.

3. The polysilicon thin film transistor of claim 1, wherein the silicon nitride layer has a thickness between about 50 Å to 400 Å.

4. The polysilicon thin film transistor of claim 1, wherein the doped source/drain region includes an N-doped region.

5. The polysilicon thin film transistor of claim 1, wherein the doped source/drain region includes a P-doped region.

6. The polysilicon thin film transistor of claim 5, wherein the poly-island layer may further include a lightly doped drain region between the channel region and the doped source/drain region.

7. The polysilicon thin film transistor of claim 1, wherein the transistor may further include a buffer layer directly formed over the substrate.

8. A polysilicon thin film transistor, comprising:
a gate;
a poly-island layer under the gate, wherein the poly-island layer further includes a channel region under the gate and a doped source/drain region on each side of the channel region;
a gate insulating film between the gate and the poly-island layer, wherein the gate insulating film includes a silicon oxide layer and a silicon nitride layer, wherein
the silicon oxide layer covers the poly-island layer; and
the silicon nitride layer is between the silicon oxide layer and the gate;
a first inter-layer dielectric over the gate and the gate insulating film;
a source/drain contact metal embedded between the first inter-layer dielectric and the gate insulating film on each side of the gate, wherein the source/drain contact metal is electrically connected to the doped source/drain region; and
a second inter-layer dielectric covering the first inter-layer dielectric and the source/drain contact metal.

9. The polysilicon thin film transistor of claim 8, wherein the silicon oxide has a thickness between about 100 Å to 1400 Å.

10. The polysilicon thin film transistor of claim 8, wherein the silicon nitride layer has a thickness between about 50 Å to 400 Å.

11. The polysilicon thin film transistor of claim 8, wherein the doped source/drain region includes an N-doped region.

12. The polysilicon thin film transistor of claim 8, wherein the doped source/drain region includes a P-doped region.

13. The polysilicon thin film transistor of claim 12, wherein the poly-island layer may further include a lightly doped drain region between the channel region and the doped source/drain region.

14. The polysilicon thin film transistor of claim 8, wherein the transistor may further include a buffer layer directly formed over the substrate.
